(19) United States
(12) Patent Application Publication
(10) Pub. No.: US 2025/0107302 A1
(43) Pub. Date: Mar. 27, 2025

(54) METHOD OF MANUFACTURING LIGHT-EMITTING DEVICE, AND LIGHT-EMITTING DEVICE

(71) Applicant: NICHIA CORPORATION, Anan-shi (JP)

(72) Inventor: Koji ABE, Tokushima-shi (JP)

(73) Assignee: NICHIA CORPORATION, Anan-shi (JP)

(21) Appl. No.: 18/887,542

(22) Filed: Sep. 17, 2024

(30) Foreign Application Priority Data
Sep. 21, 2023 (JP) 2023-155194

(51) Int. Cl. H01L 33/62; H01L 25/075; H01L 33/52

(52) U.S. Cl. CPC H10H 20/857; H01L 25/0753; H10H 20/852; H10H 20/0362; H10H 20/0364

(57) ABSTRACT

A method of manufacturing a light-emitting device includes: providing a substrate including a base, and a pair of wiring parts disposed on an upper surface side of the base; providing a light-emitting element including a semiconductor structure, and a pair of electrodes; disposing the light-emitting element above the substrate such that the electrodes face the wiring parts; disposing an electrically-conductive member containing copper such that the electrically-conductive member electrically connects the wiring parts to the electrodes and includes a body portion and a protruding portion, the body portion overlapping a corresponding wiring part of the wiring parts in a top view, and the protruding portion protruding outward such that a gap is located between the protruding portion and the base; and disposing a protective film at least in the gap in a state in which the gap is widened by heating the electrically-conductive member.

### CROSS-REFERENCE TO RELATED APPLICATIONS

The present application claims priority under 35 U.S.C. § 119 to Japanese Patent Application No. 2023-155194, filed Sep. 21, 2023, the entire contents of which are hereby incorporated by reference.

### BACKGROUND

### 1. Technical Field

The present disclosure relates to a method of manufacturing a light-emitting device, and a light-emitting device.

### 2. Description of Related Art

Light-emitting devices in which light-emitting devices are mounted on a wiring substrate are known. Japanese Patent Publication No. 04-217323 describes a method of manufacturing an electrode for connecting a semiconductor chip to the outside.

### SUMMARY

It is an object of one embodiment of the present disclosure to provide a method of manufacturing a light-emitting device with high reliability, and a light-emitting device.

A method of manufacturing a light-emitting device according to one embodiment of the present disclosure includes: preparing a substrate including a base and a pair of wiring parts disposed on an upper surface side of the base; disposing a light-emitting element, including a semiconductor structure and a pair of electrodes disposed on a lower surface of the semiconductor structure, above the substrate such that the pair of electrodes face the pair of wiring parts; disposing an electrically-conductive member containing copper such that the electrically-conductive member electrically connects the pair of wiring parts to the pair of electrodes and includes a body portion and a protruding portion, the body portion overlapping a corresponding wiring part of the pair of wiring parts in a top view, and the protruding portion protruding outward relative to the corresponding wiring part of the pair of wiring parts such that a gap is provided between the protruding portion and the base; and disposing a protective film at least in the gap by using an atomic layer deposition method in a state in which the gap is widened by heating the electrically-conductive member at a temperature of 150° C. or more and 250° C. or less.

A light-emitting device according to one embodiment of the present disclosure includes: a substrate including a base and a pair of wiring parts disposed on an upper surface side of the base; a light-emitting element including a semiconductor structure and a pair of electrodes disposed on a lower surface of the semiconductor structure; an electrically-conductive member containing copper, electrically connecting the pair of wiring parts to the pair of electrodes, and including a body portion and a protruding portion, the body portion overlapping a corresponding wiring part of the pair of wiring parts in a top view, and the protruding portion protruding outward relative to the corresponding wiring part of the pair of wiring parts such that a gap is provided between the protruding portion and the base; a protective film covering at least the gap and including a first insulating film and a second insulating film having different linear expansion coefficients from each other.

### BRIEF DESCRIPTION OF THE DRAWINGS

A more complete appreciation of embodiments of the invention and many of the attendant advantages thereof will be readily obtained by reference to the following detailed description when considered in connection with the accompanying drawings.

FIG. 1 is a schematic perspective view of an example of a light-emitting device according to an embodiment.

FIG. 2 is a schematic cross-sectional view of the light-emitting device according to the embodiment, taken through line II-II of FIG. 1.

FIG. 3 is a partially enlarged cross-sectional view schematically illustrating a cross-sectional portion of a region III of FIG. 2 in the light-emitting device according to the embodiment.

FIG. 4 is a schematic cross-sectional view illustrating an example of a method of manufacturing the light-emitting device according to the embodiment.

FIG. 5 is a schematic cross-sectional view illustrating the example of the method of manufacturing the light-emitting device according to the embodiment.

FIG. 6 is a schematic cross-sectional view illustrating the example of the method of manufacturing the light-emitting device according to the embodiment;

FIG. 7 is a schematic cross-sectional view illustrating the example of the method of manufacturing the light-emitting device according to the embodiment.

FIG. 8 is a schematic cross-sectional view illustrating the example of the method of manufacturing the light-emitting device according to the embodiment.

FIG. 9 is a schematic cross-sectional view illustrating the example of the method of manufacturing the light-emitting device according to the embodiment.

FIG. 10 is a schematic cross-sectional view illustrating the example of the method of manufacturing the light-emitting device according to the embodiment.

FIG. 11 is a schematic cross-sectional view illustrating the example of the method of manufacturing the light-emitting device according to the embodiment.

### DETAILED DESCRIPTION

In the following, a method of manufacturing a light-emitting device according to an embodiment of the present disclosure, and a light-emitting device will be described in detail with reference to the accompanying drawings. The embodiments described below are provided as examples of the method of manufacturing the light-emitting device, and the light-emitting device that embody the technical ideas of the present disclosure, but the present invention is not limited to the described embodiments. In addition, unless otherwise specified, the dimensions, materials, shapes, relative arrangements, and the like of components described in the embodiment are not intended to limit the scope of the present invention thereto, but are described as examples. The sizes, positional relationships, and the like of members illustrated in the drawings may be exaggerated for clearer illustration. Further, in the following description, the same names and reference numerals denote the same or similar members, and a detailed description thereof will be omitted as appropriate. An end view illustrating only a cut surface may be used as a cross-sectional view.

In the drawings, directions may be indicated by an X-axis, a Y-axis, and a Z-axis. The X-axis, the Y-axis, and the Z-axis are orthogonal to one another. A direction indicated by an arrow in the X-axis direction is referred to as a +X direction, and a direction opposite to the +X direction is referred to as a −X direction. A direction indicated by an arrow in the Y-axis direction is referred to as a +Y direction, and a direction opposite to the +Y direction is referred to as a −Y direction. A direction indicated by an arrow in the Z-axis direction is referred to as a +Z direction, and a direction opposite to the +Z direction is referred to as a −Z direction. Further, the term “top view” as used in the embodiment refers to viewing an object from the +Z direction. However, these directions do not limit the orientation of the light-emitting device during use, and the orientation of the light-emitting device is arbitrary. In addition, in the embodiment, a surface of an object when viewed from the +Z direction is referred to as an “upper surface”, and a surface of the object when viewed from the −Z direction is referred to as a “lower surface”. In the embodiment described below, each of the phrases “along the X-axis”, “along the Y-axis”, and “along the Z-axis” includes a case where the object is at an inclination within a range of +10° with respect to the corresponding one of the axes. Further, in the embodiment, the term “orthogonal” may include an error within +10° of 90°.

In the present disclosure, unless otherwise specified, polygonal shapes such as rectangular shapes, including polygonal shapes with rounded corners, beveled corners, angled corners, reverse-rounded corners are also referred to as polygonal shapes. Further, not only shapes with such modification at corners (end of sides) but also shapes with modifications at intermediate portions of sides of the shapes are also referred to as polygonal shapes. That is, shapes that are based on polygonal shapes and partially modified are also interpreted as “polygonal shapes” in the present disclosure.

The same applies not only to polygonal shapes but also to terms representing specific shapes such as trapezoidal shapes, circular shapes, projections, and recesses. The same also applies when referring to sides forming such a shape. That is, even when a corner or an intermediate portion of a certain side is modified, the “side” is construed as including the modified portion.

### EMBODIMENT

### Overall Configuration of Light-Emitting Device 1

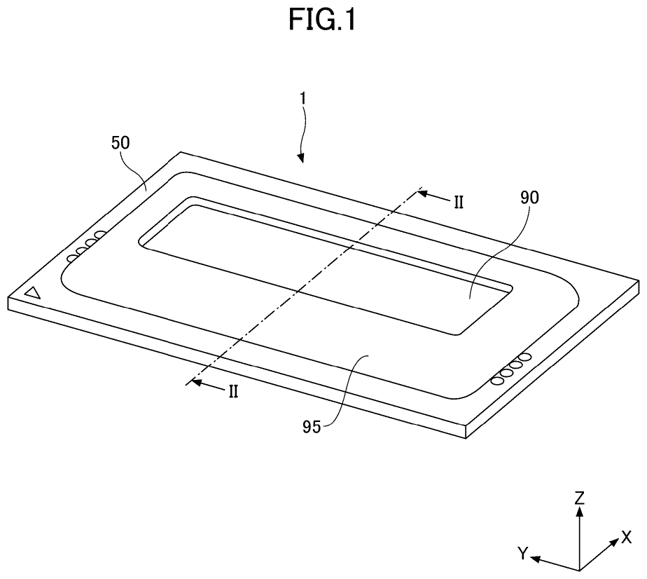

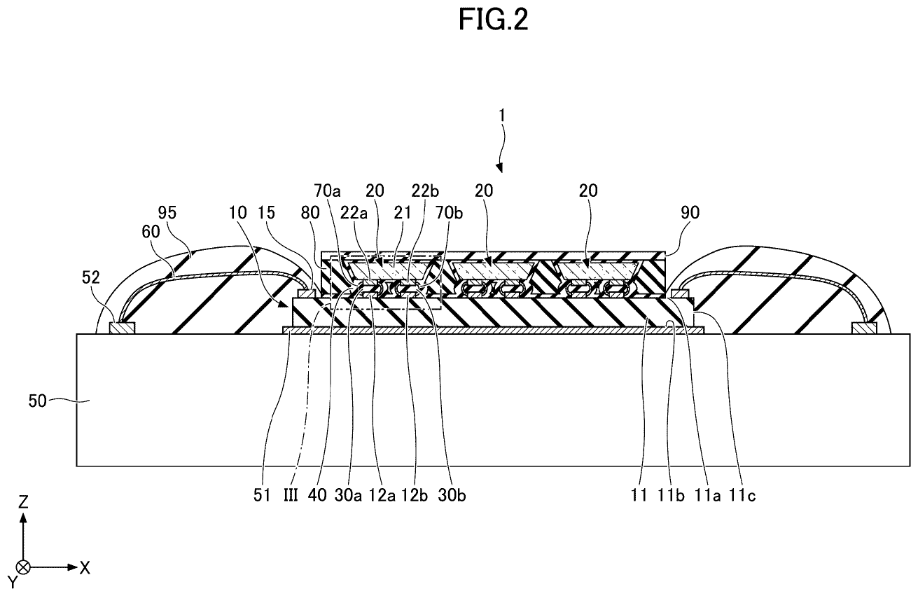

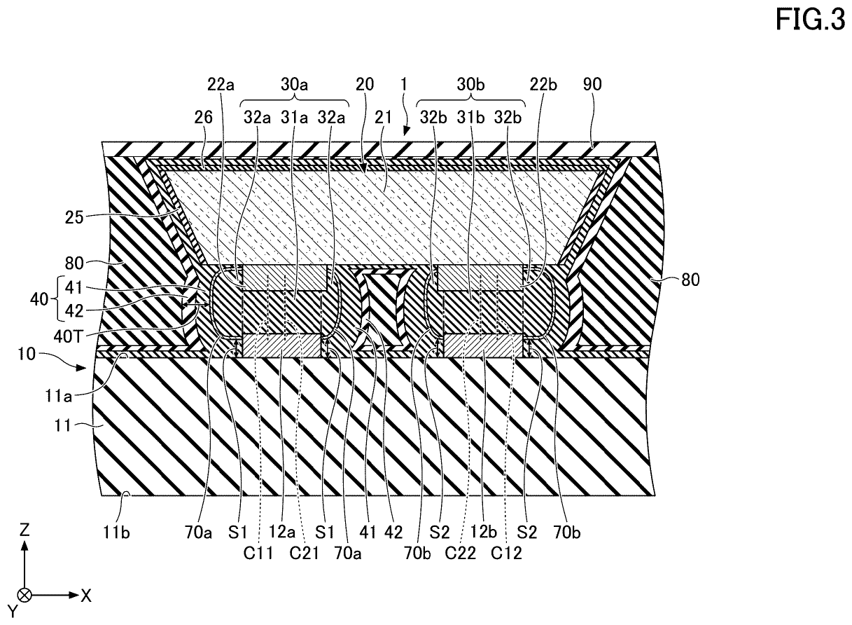

An example of a configuration of a light-emitting device 1 according to an embodiment will be described with reference to FIG. 1 to FIG. 3 as a premise for describing a method of manufacturing the light emitting device 1. FIG. 1 is a schematic perspective view of the light-emitting device 1 according to the embodiment. FIG. 2 is a schematic cross-sectional view of the light-emitting device 1 taken through line II-II of FIG. 1. FIG. 3 is a partially enlarged cross-sectional view schematically illustrating a cross-sectional portion of a region III of FIG. 2 in the light-emitting device 1 according to the embodiment.

The light-emitting device 1 includes a substrate 10, a light-emitting element 20, electrically-conductive members 30a and 30b, and a protective film 40. The light-emitting device 1 may further include a package substrate 50, a wire 60, metal layers 70a and 70b, a light-shielding member 80, a wavelength conversion member 90, and a covering member 95. FIG. 2 illustrates three light emitting-elements 20 arranged along the X direction. However, the number of the light emitting elements 20 included in the light-emitting device 1 is not limited to three.

As illustrated in FIG. 2, the lower surface of the substrate 10 is bonded to the upper surface of the package substrate 50 with a bonding member 51 interposed therebetween, for example. A first terminal 15 provided on the upper surface of the substrate 10 is electrically connected to a second terminal 52 provided on the upper surface of the package substrate 50 via the wire 60. The second terminal 52 of the package substrate 50 is electrically connected to an external power source. That is, the first terminal 15 provided on the upper surface of the substrate 10 is electrically connected to the external power source via the second terminal 52 of the package substrate 50 and the wire 60. The wire 60 is covered by the covering member 95.

### Substrate 10

The substrate 10 has a substantially rectangular outer shape in a top view. However, the substrate 10 may have any other outer shape, such as a substantially circular shape, a substantially elliptical shape, or a substantially polygonal shape in a top view. The substrate 10 may include an integrated circuit for controlling the light emitting operation of the light-emitting element 20. Examples of the integrated circuit include an electronic circuit such as an application specific integrated circuit (ASIC).

As illustrated in FIG. 3, the substrate 10 includes a base 11 and a pair of wiring parts 12a and 12b. The substrate 10 further includes the first terminal 15 (see FIG. 2). The pair of wiring parts 12a and 12b are electrically connected to the first terminal 15 via, for example, internal wiring provided inside the base 11.

The base 11 is a base of the substrate 10. As illustrated in FIG. 3, the base 11 has an upper surface 11a, a lower surface 11b, and lateral surfaces 11c connecting the outer edge of the upper surface 11a and the outer edge the lower surface 11b. The base 11 is mainly composed of an insulator having an insulating property or composed of a semiconductor material. Examples of the material constituting the base 11 include a semiconductor substrate such as silicon, a ceramic substrate such as aluminum nitride, and a resin substrate such as glass epoxy. However, the material constituting the base 11 is not limited thereto.

Each of the wiring parts 12a and 12b has a substantially rectangular outer shape in a top view. However, each of the wiring parts 12a and 12b may have any other outer shape, such as a substantially circular shape, a substantially elliptical shape, or a substantially polygonal shape in a top view.

Each of the wiring parts 12a and 12b contains, for example, copper. However, the material constituting each of the wiring parts 12a and 12b is not limited to copper. Other examples of the material constituting each of the wiring parts 12a and 12b include gold, silver, aluminum, nickel, rhodium, titanium, platinum, palladium, molybdenum, chromium, and tungsten.

The wiring part 12a is disposed on the upper surface 11a side of the base 11. The wiring part 12a illustrated in FIG. 3 is disposed on the upper surface 11a of the base 11. However, the wiring part 12a may be disposed in the base 11 such that the upper surface of the wiring part 12a is exposed through the upper surface 11a of the base 11. The wiring part 12a may be bonded to the base 11 via a bonding layer composed of, for example, a metal, an alloy, or the like.

The wiring part 12b is disposed on the upper surface 11a side of the base 11 and is disposed at a position spaced apart from the wiring part 12a. The wiring part 12b illustrated in FIG. 3 is disposed on the upper surface 11a of the base 11. However, the wiring part 12b may be disposed in the base 11 such that the upper surface of the wiring part 12b is exposed through the upper surface 11a of the base 11. The wiring part 12b may be bonded to the base 11 via a bonding layer composed of, for example, a metal, an alloy, or the like.

### Light-Emitting Element 20

The light-emitting element 20 is a semiconductor light-emitting element such as a light emitting diode (LED) or a laser diode (LD). As illustrated in FIG. 3, the light-emitting element 20 includes a semiconductor structure 21 and a pair of electrodes 22a and 22b. Further, the light-emitting element 20 may include a lateral surface covering layer 25 that covers the lateral surfaces of the semiconductor structure 21 and an upper surface covering layer 26 that covers the upper surface of the semiconductor structure 21.

The semiconductor structure 21 emits, for example, blue light. The semiconductor structure 21 includes an n-type semiconductor layer, an active layer, and a p-type semiconductor layer that are sequentially layered in the Z direction. The n-type semiconductor layer, the active layer, and the p-type semiconductor layer of the semiconductor structure 21 are composed of, for example, nitride-based semiconductors such as In_{X}Al_{Y}Ga_{1-X-Y}N (0≤x, 0≤y, x+y≤1). The upper surface (the surface on the +Z side) of the semiconductor structure 21 corresponds to a light extraction surface.

The semiconductor structure 21 has a substantially rectangular outer shape in a top view. However, the semiconductor structure 21 may have any other outer shape, such as a substantially circular shape, a substantially elliptical shape, or a substantially polygonal shape in a top view. The semiconductor structure 21 illustrated in FIG. 3 has a trapezoidal shape in a cross-sectional view. However, the shape of the semiconductor structure 21 in a cross-sectional view is not limited to a trapezoidal shape.

Each of the electrodes 22a and 22b is disposed on the lower surface of the semiconductor structure 21. The electrodes 22a and 22b are positive and negative electrodes disposed at positions spaced apart from each other on the lower surface of the semiconductor structure 21. Each of the electrodes 22a and 22b contains a metal such as gold.

Each of the electrodes 22a and 22b has a substantially rectangular outer shape in a top view. However, each of the electrodes 22a and 22b may have any other outer shape, such as a substantially circular shape, a substantially elliptical shape, or a substantially polygonal shape in a top view. The electrode 22a and the wiring part 12a face each other with the electrically-conductive member 30a interposed therebetween. The electrode 22b and the wiring part 12b face each other with the electrically-conductive member 30b interposed therebetween.

The lateral surface covering layer 25 is an insulating layer that protects the lateral surfaces of the semiconductor structure 21. The upper surface covering layer 26 is an insulating layer that protects the upper surface of the semiconductor structure 21. The lateral surface covering layer 25 and the upper surface covering layer 26 may be disposed on the semiconductor structure 21 in separate steps, for example. The lateral surface covering layer 25 and the upper surface covering layer 26 are preferably composed of the same material. Examples of the material constituting each of the lateral surface covering layer 25 and the upper surface covering layer 26 include silicon oxide, aluminum oxide, silicon nitride, tantalum oxide, and niobium oxide. However, the configurations of the lateral surface covering layer 25 and the upper surface covering layer 26 are not limited thereto.

The upper surface covering layer 26 overlaps the upper surface corresponding to the light extraction surface of the semiconductor structure 21 in a top view. The thickness of the upper surface covering layer 26 is preferably smaller than the thickness of the lateral surface covering layer 25. With this configuration, an influence of the upper surface covering layer 26 on the light extraction efficiency of the semiconductor structure 21 can be reduced. However, the thickness of the lateral surface covering layer 25 and the thickness of the upper surface covering layer 26 may be substantially the same.

### Electrically-Conductive Members 30a and 30b

As illustrated in FIG. 3, each of the electrically-conductive members 30a and 30b is disposed between the substrate 10 and the light-emitting element 20. The electrically-conductive member 30a electrically connects the wiring part 12a of the substrate 10 to the electrode 22a of the light-emitting element 20. The electrically-conductive member 30b is disposed at a position spaced apart from the electrically-conductive member 30a, and electrically connects the wiring part 12b of the substrate 10 to the electrode 22b of the light-emitting element 20.

Each of the electrically-conductive members 30a and 30b contains copper. Because each of the electrically-conductive members 30a and 30b contains copper having good electrical conductivity and thermal conductivity, the electrical resistance of each of the electrically-conductive members 30a and 30b can be reduced, and the heat dissipation of the light-emitting element 20 can be improved.

In a cross section passing through the semiconductor structure 21 and the pair of electrodes 22a and 22b, a center C11 of the electrically-conductive member 30a in the width direction is preferably located outward (on the −X side) relative to a center C21 of the electrode 22a in the width direction. A center C12 of the electrically-conductive member 30b in the width direction is preferably located outward (on the +X side) relative to a center C22 of the electrode 22b in the width direction. Accordingly, the distance between the electrically-conductive member 30a and the electrically-conductive member 30b can be increased. As a result, the possibility that the electrically-conductive member 30a and the electrically-conductive member 30b may contact each other and may be short-circuited can be reduced. As used herein, the term “outward” or “outside” refers to a side farther from an imaginary line passing through the center of the light-emitting element 20 and extending in the Z direction in a cross-sectional view. Further, the term “center” refers to the geometric center of gravity of the shape of an object in a cross-sectional view.

As illustrated in FIG. 3, the electrically-conductive member 30a includes a body portion 31a and a protruding portion 32a. The body portion 31a overlaps the wiring part 12a in a top view. Further, the body portion 31a is disposed between the upper surface of the wiring part 12a and the lower surface of the electrode 22a. The protruding portion 32a protrudes outward relative to the wiring part 12a in a top view. The protruding portion 32a is not bonded to the upper surface 11a of the base 11. Therefore, a gap S1 is formed between the protruding portion 32a and the upper surface 11a of the base 11. The illustrated protruding portion 32a does not contact the upper surface 11a of the base 11; however, a portion of the protruding portion 32a may contact the upper surface 11a of the base 11. In this case, a gap S1 is formed in a non-contact region between the protruding portion 32a and the upper surface 11a of the base 11. The protective film 40 is interposed in the gap S1.

The electrically-conductive member 30b includes a body portion 31b and a protruding portion 32b. The body portion 31b overlaps the wiring part 12b in a top view. Further, the body portion 31b is disposed between the upper surface of the wiring part 12b and the lower surface of the electrode 22b. The protruding portion 32b protrudes outward relative to the wiring part 12b in a top view. The protruding portion 32b is not bonded to the upper surface 11a of the base 11. Therefore, a gap S2 is formed between the protruding portion 32b and the upper surface 11a of the base 11. The illustrated protruding portion 32b does not contact the upper surface 11a of the base 11; however, a portion of the protruding portion 32b may contact the upper surface 11a of the base 11. In this case, a gap S2 is formed in a non-contact region between the protruding portion 32b and the upper surface 11a of the base 11. The protective film 40 is interposed in the gap S2 between the protruding portion 32b and the upper surface 11a of the base 11.

In the electrically-conductive member 30a, if the body portion 31a is structurally integrated with the protruding portion 32a, the protruding portion 31a does not substantially exist as a separate portion from the body portion 32a; however, the protruding portion 32a can be conceptually defined as indicated by a two-dot dash line of FIG. 3, and can be regarded as a conceptual portion. The same applies to the body portion 31b and the protruding portion 32b of the electrically-conductive member 30b.

### Metal Layers 70a and 70b

The metal layer 70a covers the surface of the protruding portion 32a. When the metal layer 70a covers the surface of the protruding portion 32a, the electrically-conductive member 30a can be protected from a corrosive substance such as airborne sulfur present on the outside (hereinafter referred to as a “corrosive substance”). The metal layer 70a may cover regions other than the surface of the protruding portion 32a, such as the lateral surfaces of the wiring part 12a and the lateral surfaces of the electrode 22a.

The metal layer 70b covers the surface of the protruding portion 32b. When the metal layer 70b covers the surface of the protruding portion 32b, the electrically-conductive member 30b can be protected from the corrosive substance. The metal layer 70b may cover regions other than the surface of the protruding portion 32b, such as the lateral surfaces of the wiring part 12b and the lateral surfaces of the electrode 22b.

Each of the metal layers 70a and 70b may include a plurality of layers. For example, each of the metal layers 70a and 70b includes a first layer, a second layer, and a third layer. The first layer, the second layer, and the third layer of the metal layer 70a are stacked in this order from the surface of the protruding portion 32a toward the outside. The first layer, the second layer, and the third layer of the metal layer 70b are stacked in this order from the surface of the protruding portion 32b toward the outside. However, the configuration of each of the metal layers 70a and 70b is not limited to the three-layer structure including the first layer, the second layer, and the third layer.

Examples of a metal constituting the first layer include gold. Examples of a metal constituting the second layer include palladium. Examples of a metal constituting the third layer include gold. However, the metals constituting the first layer, the second layer, and the third layer are not limited thereto. The first layer containing gold can protect the electrically-conductive members 30a and 30b containing copper from the corrosive substance. In addition, the first layer containing gold has good adhesion to the second layer containing palladium and the electrically-conductive members 30a and 30b containing copper, and thus functions as a bonding member that bonds the second layer to the electrically-conductive members 30a and 30b. The second layer containing palladium functions as a diffusion prevention layer that reduces diffusion of copper from the electrically-conductive members 30a and 30b. The third layer containing gold protects the electrically-conductive members 30a and 30b containing copper from the corrosive substance.

### Protective Film 40

As illustrated in FIG. 3, the protective film 40 covers at least the gap S1 between the protruding portion 32a and the upper surface 11a of the base 11 and the gap S2 between the protruding portion 32b and the upper surface 11a of the base 11.

The protective film 40 covering the gap S1 and the gap S2 preferably extends deeper into the gap S1 and deeper into the gap S2 in a such that the protective film 40 is in close contact with the upper surface 11a of the base 11. As used herein, “extending deeper into the gap S1” refers to extending to a region located closest to the electrically-conductive member 30a and between the protruding portion 32a and the upper surface 11a of the base 11. Further, the “extending deeper into the gap S2” refers to extending to a region located closest to the electrically-conductive member 30b and between the protruding portion 32b and the upper surface 11a of the base 11.

The electrically-conductive members 30a and 30b contain copper having a relatively high linear expansion coefficient, and thus the electrically-conductive members 30a and 30b may thermally expand to a great degree when being exposed to a high-temperature environment during, for example, a process of disposing the light-shielding member 80 or during the operation of the light-emitting device 1. At this time, the gap S1 is widened according to the thermal expansion of the electrically-conductive member 30a, and the gap S2 is widened according to the thermal expansion of the electrically-conductive member 30b. If the gap S1 and the gap S2 are widened and the protective film is not sufficiently disposed in the gaps S1 and S2, the corrosive substance that has entered the gaps S1 and S2 from the outside would reach the electrically-conductive members 30a and 30b. As a result, a portion of each of the electrically-conductive members 30a and 30b would be converted into copper sulfide or the like, and bondability or heat dissipation would be deteriorated. Conversely, in the light-emitting device 1 according to the present disclosure, the protective film 40 extends deeper into the gaps S1 and S2, and thus, even when the electrically-conductive members 30a and 30b thermally expand, the protective film 40 and the base 11 maintain close contact with each other. That is, even when the electrically-conductive members 30a and 30b are exposed to a high-temperature environment, a gap is unlikely to be formed between the protective film 40 and the base 11 due to the thermal expansion of the electrically-conductive members 30a and 30b. Accordingly, the possibility that the corrosive substance may enter the inside of the protective film 40 through a gap between the protective film 40 and the base 11 and corrode the electrically-conductive members 30a and 30b can be reduced. As a result, the reliability of the light-emitting device 1 can be further improved.

The protective film 40 illustrated in FIG. 3 includes a first insulating film 41 and a second insulating film 42 having different linear expansion coefficients from each other. The first insulating film 41 and the second insulating film 42 are stacked in this order from the surface of each of the electrically-conductive members 30a and 30b toward the outside. The first insulating film 41 covers the gaps S1 and S2. The second insulating film 42 covers the surface of the first insulating film 41 on the side opposite to the gaps S1 and S2.

The linear expansion coefficient of the first insulating film 41 and the linear expansion coefficient of the second insulating film 42 are different from each other. Thus, for example, formation of a series of cracks across both the first insulating film 41 and the second insulating film 42 due to the thermal expansion of the electrically-conductive members 30a and 30b exposed to a high-temperature environment can be reduced. That is, the occurrence of cracks penetrating through the protective film 40 can be reduced. As a result, the possibility that the corrosive substance may enter the inside of the protective film 40 and corrode the electrically-conductive members 30a and 30b can be further reduced.

The linear expansion coefficient of the first insulating film 41 is preferably greater than the linear expansion coefficient of the second insulating film 42. Further, the linear expansion coefficient of the first insulating film 41 is preferably closer to the linear expansion coefficient of copper contained in the electrically-conductive member 30a than the linear expansion coefficient of the second insulating film 42. Accordingly, the first insulating film 41 of the protective film 40, which has a linear expansion coefficient close to the linear expansion coefficient of copper, can be disposed at a position closest to the electrically-conductive members 30a and 30b. In consideration of the relationship with the linear expansion coefficients of the electrically-conductive members 30a and 30b, the first insulating film 41 can be deformed in response to the thermal expansion of the electrically-conductive members 30a and 30b, and thus the occurrence of cracks in the first insulating film 41 can be reduced. Further, the first insulating film 41 is interposed between the second insulating film 42 and the electrically-conductive members 30a and 30b. Thus, rapid deformation of the second insulating film 42 when the electrically-conductive members 30a and 30b thermally expand can be alleviated. As a result, the occurrence of cracks in the second insulating film 42 can be reduced.

As examples of the first insulating film 41 and the second insulating film 42 having such a magnitude relationship of linear expansion coefficients, the first insulating film 41 may be a film containing aluminum oxide and the second insulating film 42 may be a film containing silicon oxide. When the second insulating film 42 covering the first insulating film 41 contains silicon oxide having good barrier performance against a sulfur-based gas, the gas barrier property of the protective film 40 can be improved.

The protective film 40 illustrated in FIG. 3 includes one first insulating film 41 and one second insulating film 42. However, the protective film 40 may include a plurality of first insulating films 41 and a plurality of second insulating films 42. In this case, the first insulating films 41 and the second insulating films 42 are alternately arranged. Further, a thickness 40T of the protective film 40 is preferably 1.5 times or more and 2.5 times or less the dimension of the gap S1 along the Z direction. Similarly, the thickness 40T of the protective film 40 is preferably 1.5 times or more and 2.5 times or less the dimension of the gap S2 along the Z direction. Accordingly, the occurrence of cracks in the protective film 40 due to the thermal expansion of the electrically-conductive members 30a and 30b can be further reduced.

The protective film 40 preferably covers the surface of the protruding portion 32a. The protective film 40 illustrated in FIG. 3 covers the surface of the protruding portion 32a via the metal layer 70a. Further, the protective film 40 preferably covers the surface of the protruding portion 32b. The protective film 40 illustrated in FIG. 3 covers the surface of the protruding portion 32b via the metal layer 70b. Accordingly, the possibility that the corrosive substance may enter the inside of the protective film 40 and corrode the electrically-conductive members 30a and 30b can be further reduced.

The protective film 40 preferably integrally covers the lateral surface covering layer 25 and the upper surface covering layer 26 of the light-emitting element 20. When the protective film 40 integrally covers the lateral surface covering layer 25 and the upper surface covering layer 26 of the light-emitting element 20, peeling of the lateral surface covering layer 25 and the upper surface covering layer 26 can be reduced. In addition, peeling of a boundary portion between the lateral surface covering layer 25 and the upper surface covering layer 26, which has relatively low adhesion to the semiconductor structure 21, can be reduced.

The thickness of a region of the protective film 40 covering the upper surface covering layer 26 is preferably smaller than the thickness of a region of the protective film 40 covering the lateral surface covering layer 25. The region of the protective film 40 covering the upper surface covering layer 26 overlaps the upper surface corresponding to the light extraction surface of the semiconductor structure 21 in a top view. Therefore, by making the thickness of the region of the protective film 40 covering the upper surface covering layer 26 smaller than the thickness of the region of the protective film 40 covering the lateral surface covering layer 25, an influence of the protective film 40 on the light extraction efficiency of the semiconductor structure 21 can be reduced.

### Light-Shielding Member 80

The light-shielding member 80 covers the lateral surfaces of the semiconductor structure 21. The light-shielding member 80 illustrated in FIG. 3 covers the lateral surface of the semiconductor structure 21 via the protective film 40 and the lateral surface covering layer 25. The light-shielding member 80 preferably has light reflectivity. When the light-shielding member 80 having light reflectivity covers the lateral surfaces of the semiconductor structure 21, light from the semiconductor structure 21 can be emitted in a predetermined direction. For example, the light-shielding member 80 is composed of a resin material containing a light reflective substance. Examples of the light reflective substance include titanium oxide, zinc oxide, magnesium oxide, magnesium carbonate, magnesium hydroxide, calcium carbonate, calcium hydroxide, calcium silicate, magnesium silicate, barium titanate, barium sulfate, aluminum hydroxide, aluminum oxide, zirconium oxide, and silicon oxide. It is preferable to use one of these substances alone or a combination of two or more of these substances. Further, examples of the resin material include resin materials whose main components are thermosetting resins such as an epoxy resin, an epoxy-modified resin, a silicone resin, a silicone-modified resin, and a phenol resin.

### Wavelength Conversion Member 90

The wavelength conversion member 90 is disposed above the light-emitting element 20. The wavelength conversion member 90 converts a wavelength of light emitted from the semiconductor structure 21 of the light-emitting element 20. The wavelength conversion member 90 includes a base and a wavelength conversion substance. The base includes a light transmissive substance, and the wavelength conversion substance is disposed inside the base. As used herein, “light transmissive” means that 60% or more of the light emitted from the semiconductor structure 21 is transmitted. Examples of the light transmissive substance include a resin material, a ceramic, and glass. In the present embodiment, the light transmissive substance constituting the base includes a resin material. Examples of the resin material include a silicone resin, a silicone-modified resin, an epoxy resin, an epoxy-modified resin, and a phenol resin. In particular, a silicone resin or a modified resin thereof having good light resistance and heat resistance is preferably used. However, the light transmissive substance is not limited thereto.

Examples of the wavelength conversion substance include yttrium aluminum garnet based phosphors (hereinafter referred to as “YAG phosphors”, for example, (Y,Gd)₃(Al,Ga)₅O₁₂:Ce), lutetium aluminum garnet based phosphors (for example, Lu₃(Al,Ga)₅O₁₂:Ce), terbium aluminum garnet based phosphors (for example, Tb₃(Al,Ga)₅O₁₂:Ce), CCA based phosphors (for example, Ca₁₀(PO₄)₆Cl₂:Eu), SAE based phosphors (for example, Sr₄Al₁₄O₂₅:Eu), chlorosilicate based phosphors (for example, CasMgSi₄O₁₆Cl₂:Eu), silicate based phosphors (for example, (Ba,Sr,Ca,Mg)₂SiO₄:Eu), oxynitride based phosphors such as β-SiAlON based phosphors (for example, (Si,Al)₃(O,N)₄:Eu) and α-SiAlON based phosphors (for example, Ca(Si,Al)₁₂(O,N)₁₆: Eu), nitride based phosphors such as LSN based phosphors (for example, (La,Y)₃Si₆N₁₁:Ce), BSESN based phosphors (for example, (Ba,Sr)₂Si₅N₈:Eu), SLA based phosphors (for example, SrLiAl₃N₄:Eu), CASN based phosphors (for example, CaAlSiN₃:Eu), and SCASN based phosphors (for example, (Sr,Ca)AlSiN₃:Eu), fluoride based phosphors such as KSF based phosphors (for example, K₂SiF₆:Mn), KSAF based phosphors (for example, K₂(Si₁₋ₓAlₓ)F₆₋ₓ:Mn, where x satisfies 0<x<1), and MGF based phosphors (for example, 3.5MgO·0.5MgF₂·GeO₂:Mn), quantum dots having a Perovskite structure (for example, (Cs,FA,MA)(Pb,Sn)(F,Cl,Br,I)₃, where FA and MA represent formamidinium and methylammonium, respectively), II-VI quantum dots (for example, CdSe), III-V quantum dots (for example, InP), and quantum dots having a chalcopyrite structure (for example, (Ag,Cu)(In,Ga)(S,Se)₂). The wavelength conversion substance according to the present embodiment includes a yttrium aluminum garnet (YAG) based phosphor having good heat resistance. For example, a portion of blue light emitted from the light-emitting element 20 is converted into yellow light by the YAG based phosphor. Accordingly, white light is emitted from the light extraction surface of the semiconductor structure 21.

### Covering Member 95

The covering member 95 includes a resin containing a filler having a light shielding property. Examples of the resin include a silicone resin, a modified silicone resin, an epoxy resin, a modified epoxy resin, and an acrylic resin. Examples of the filler having a light shielding property include light absorbing substances such as pigments, carbon black, titanium black, and graphite; and light reflective substances such as titanium oxide, aluminum oxide, zinc oxide, barium carbonate, barium sulfate, boron nitride, aluminum nitride, and a glass filler. Examples of the external color of the covering member 95 include white having good light reflectivity, black having good light absorbency, and gray having light reflectivity and light absorbency.

### Method of Manufacturing Light-Emitting Device 1

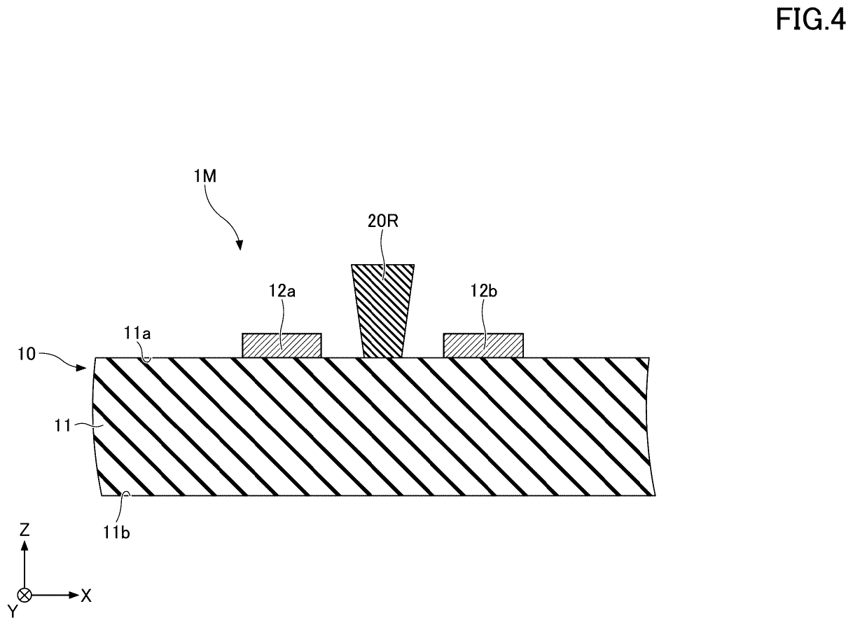

Next, a method of manufacturing the light-emitting device 1 according to the embodiment will be described with reference to FIG. 4 to FIG. 11. The method of manufacturing the light-emitting device 1 according to the embodiment includes a step of preparing a substrate 10, a step of disposing a light-emitting element 20 above the substrate 10, a step of disposing electrically-conductive members 30a and 30b, and a step of disposing a protective film 40.

The method of manufacturing the light-emitting device 1 according to the embodiment may further include a step of forming a resist layer 20R, a step of removing the resist layer 20R, a step of forming metal layers 70a and 70b, a step of covering the upper surface and the lateral surfaces of a semiconductor structure 21 with a light-shielding member 80, and a step of removing each of a region 81 of the light-shielding member 80 overlapping an upper surface covering layer 26 in a top view and an upper-side region 45 of a region of the protective film 40 overlapping the upper surface covering layer 26 in a top view. Each of the steps will be described in detail below.

First, the step of preparing the substrate 10 is performed. Specifically, the substrate 10 including a base 11 and a pair of wiring parts 12a and 12b is prepared.

Subsequently, as illustrated in FIG. 4, the step of forming the resist layer 20R is performed. Specifically, the resist layer 20R is formed on an upper surface 11a of the base 11. The resist layer 20R covers a region between the wiring part 12a and the wiring part 12b on the upper surface 11a of the base 11. However, the position at which the resist layer 20R is formed is not limited thereto.

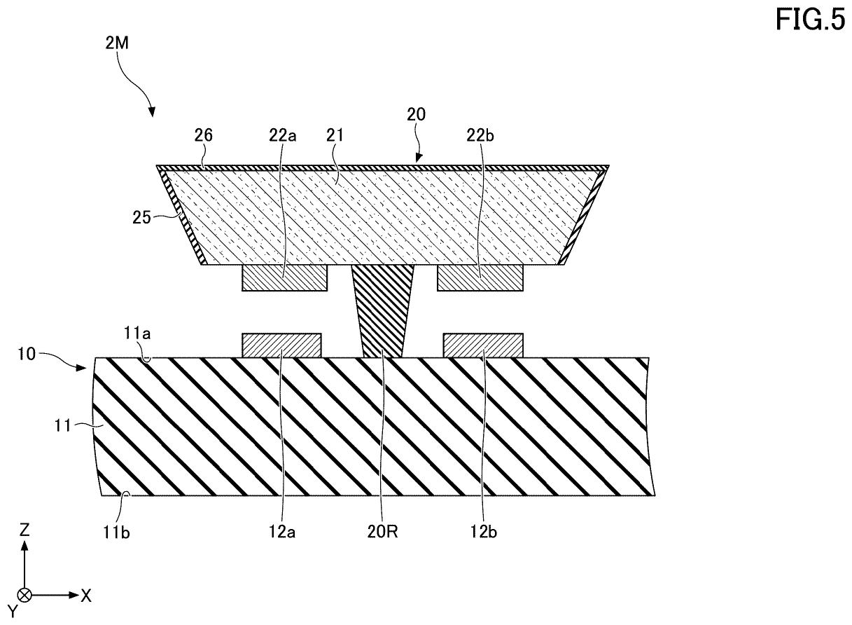

Examples of a method of forming the resist layer 20R include a photolithography method. However, the method of forming the resist layer 20R is not limited thereto. By performing the step of forming the resist layer 20R, a first intermediate body 1M is obtained. Subsequently, as illustrated in FIG. 5, the step of disposing the light-emitting element 20 above the substrate 10 is performed. Specifically, the light-emitting element 20 is disposed above the substrate 10 such that a pair of electrodes 22a and 22b disposed on the lower surface of a semiconductor structure 21 face the pair of wiring parts 12a and 12b disposed on the upper surface 11a of the base 11. Accordingly, the electrode 22a and the wiring part 12a face each other and the electrode 22b and the wiring part 12b face each other in a state in which the semiconductor structure 21 is supported by the resist layer 20R. By performing the step of disposing the light-emitting element 20 above the substrate 10, a second intermediate body 2M is obtained.

If the light-emitting element 20 includes a lateral surface covering layer 25 and an upper surface covering layer 26, the lateral surface covering layer 25 is disposed on the lateral surfaces of the semiconductor structure 21 and the upper surface covering layer 26 is disposed on the upper surface of the semiconductor structure 21 at an appropriate timing before or after the light-emitting element 20 is disposed above the substrate 10. The lateral surface covering layer 25 and the upper surface covering layer 26 may be disposed on the semiconductor structure 21 in separate steps, for example. For example, after the lateral surface covering layer 25 is disposed on the lateral surfaces of the semiconductor structure 21, a roughening step is performed on a semiconductor layer located on the upper surface of the semiconductor structure 21. By performing the roughening step, a plurality of recesses and projections are formed in the semiconductor layer located on the upper surface of the semiconductor structure 21. Thereafter, to protect the plurality of recesses and projections, the upper surface covering layer 26 is disposed on the upper surface of the semiconductor structure 21. The above step is an example, and the roughening step is not necessarily performed. Examples of a method of disposing the lateral surface covering layer 25 and the upper surface covering layer 26 include dry processes such as a sputtering method, a vacuum deposition method, and an atomic layer deposition method, and wet processes such as an ink jet method, a spin coating method, and a dipping method. However, the method of disposing the lateral surface covering layer 25 and the upper surface covering layer 26 is not limited thereto.

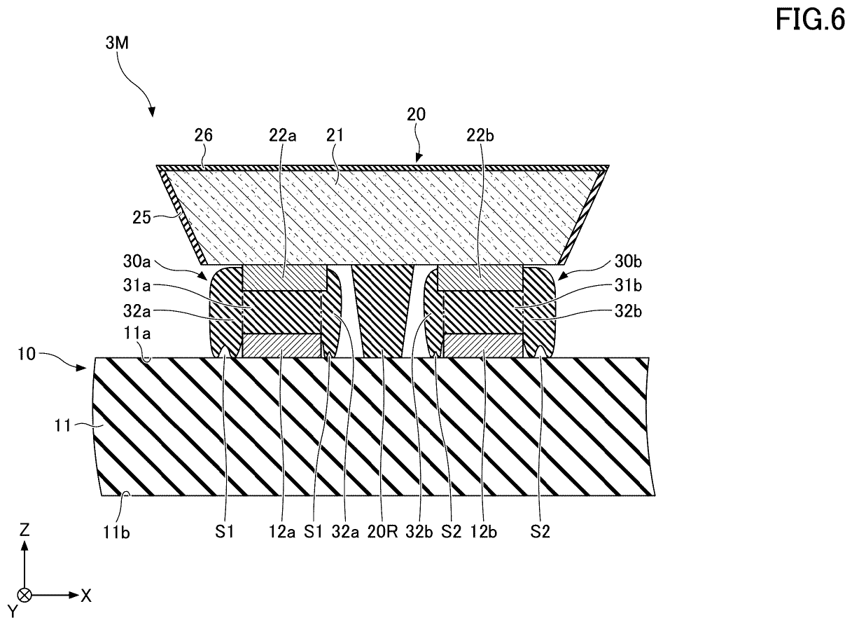

Subsequently, as illustrated in FIG. 6, the step of disposing the electrically-conductive members 30a and 30b is performed. Specifically, the electrically-conductive member 30a is disposed such that the electrically-conductive member electrically connects the wiring part 12a to the electrode 22a, and includes a body portion 31a overlapping the wiring part 12a in a top view and a protruding portion 32a protruding outward relative to the wiring part 12a such that a gap S1 is provided between the protruding portion 32a and the base 11. Similarly, the electrically-conductive member 30b is disposed such that the electrically-conductive member 30b electrically connects the wiring part 12b to the electrode 22b, and includes a body portion 31b overlapping the wiring part 12b in a top view and a protruding portion 32b protruding outward relative to the wiring part 12b such that a gap S2 is provided between the protruding portion 32b and the base 11.

Examples of a method of disposing the electrically-conductive members 30a and 30b include an electrolytic plating method. If the material constituting the wiring part 12a is a metal, the wiring part 12a can be used as a seed layer for disposing the electrically-conductive member 30a. If the material constituting the wiring part 12b is a metal, the wiring part 12b can be used as a seed layer for disposing the electrically-conductive member 30b.

In a case where the electrically-conductive members 30a and 30b are disposed by the electrolytic plating method, first, the second intermediate body 2M (see FIG. 5) and copper electrode members are immersed in an electrolytic plating solution. Next, an external voltage is applied to the second intermediate body 2M and the copper electrode members such that the wiring parts 12a and 12b of the second intermediate body 2M serve as cathodes and the copper electrode members serve as anodes. Accordingly, the electrically-conductive member 30a connecting the wiring part 12a and the electrode 22a is disposed, and the electrically-conductive member 30b connecting the wiring part 12b and the electrode 22b is disposed.

In a case where the electrically-conductive members 30a and 30b are disposed by the above-described method, plating grows in the Z direction from the wiring parts 12a and 12b toward the electrodes 22a and 22b. At this time, a portion of the plating extends beyond the upper surface of each of the wiring parts 12a and 12b in a lateral direction (the X direction or the Y direction), and is disposed on the upper surface 11a of the base 11. The portion of the plating extending outward of the wiring parts 12a and 12b corresponds to each of the protruding portions 32a and 32b. The base 11 is an insulator or a semiconductor. Therefore, the protruding portions 32a and 32b disposed on the upper surface 11a of the base 11 have a low fixing strength to the base 11, and thus the gaps S1 and S2 are formed between the protruding portions 32a and 32b and the upper surface 11a of the base 11.

The step of disposing the electrically-conductive members 30a and 30b is preferably performed such that, in a cross section passing through the semiconductor structure 21 and the pair of electrodes 22a and 22b, the center of one of the electrically-conductive members 30a and 30b in the width direction is located outward of the center of one of the electrodes 22a and 22b in the width direction, and the center of the other of the electrically-conductive members 30a and 30b in the width direction is located outward of the center of the other of the electrodes 22a and 22b in the width direction. Accordingly, the distance between the electrically-conductive member 30a and the electrically-conductive member 30b can be increased. As a result, the possibility that the electrically-conductive member 30a and the electrically-conductive member 30b may contact each other and may be short-circuited can be reduced. For example, in a top view, (i) a surface of the wiring part 12a facing the wiring part 12b is located outward relative to a surface of the electrode 22a facing the electrode 22b, and (ii) the center of the wiring part 12a is located outward relative to the center of the electrode 22a. The same applies to the wiring part 12b and the electrode 22b. In this state, the electrically-conductive members 30a and 30b are disposed by the electrolytic plating method. Accordingly, the electrically-conductive members 30a and 30b can be disposed sufficiently spaced apart from each other.

However, the method of disposing the electrically-conductive members 30a and 30b is not limited thereto. By performing the step of disposing the electrically-conductive members 30a and 30b, a third intermediate body 3M is obtained.

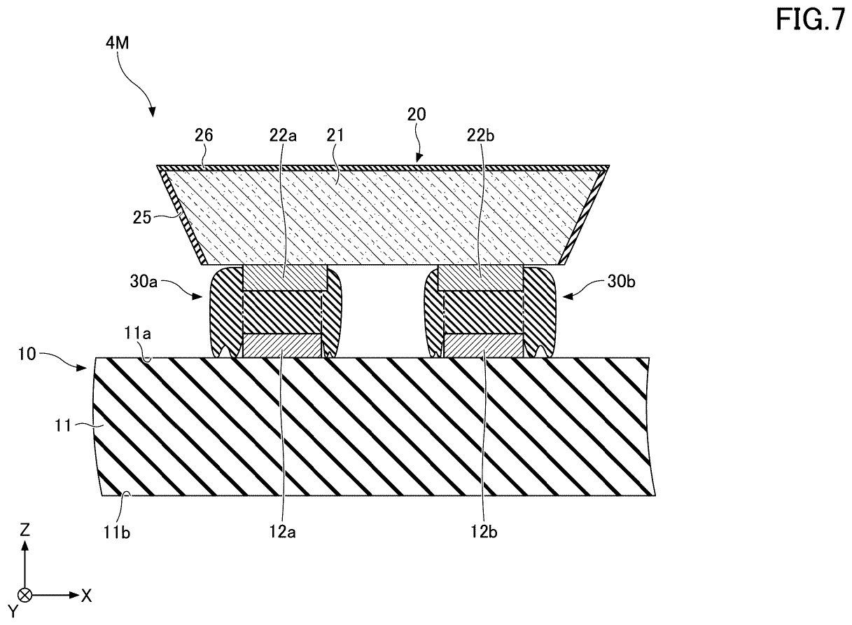

Subsequently, as illustrated in FIG. 7, the step of removing the resist layer 20R is performed. For example, to remove the resist layer 20R, the third intermediate body 3M (see FIG. 6) is immersed in a peeling solution. In this manner, the resist layer 20R is removed. However, the method of removing the resist layer 20R is not limited thereto. By performing the step of removing the resist layer 20R, a fourth intermediate body 4M is obtained

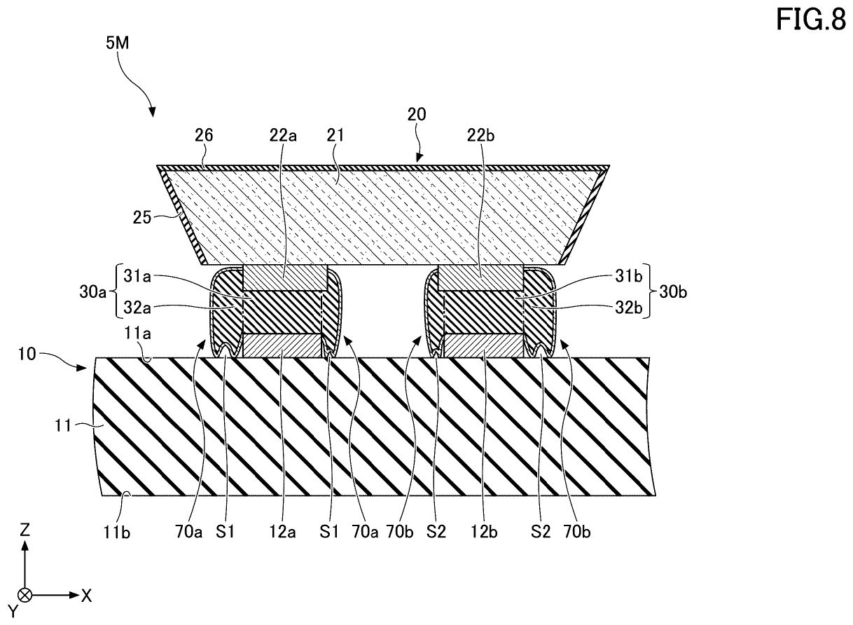

Subsequently, as illustrated in FIG. 8, a step of forming the metal layers 70a and 70b is performed. Specifically, the metal layer 70a is formed on the surface of the protruding portion 32a of the electrically-conductive member 30a, and the metal layer 70b is formed on the surface of the protruding portion 32b of the electrically-conductive member 30b.

Examples of a method of forming the metal layers 70a and 70b include an electroless plating method. In a case where the metal layers 70a and 70b are formed by the electroless plating method, the fourth intermediate body 4M (see FIG. 7) is immersed sequentially in a first electroless plating solution, a second electroless plating solution, and a third electroless plating solution. As a result, a first layer, a second layer, and a third layer are sequentially formed on the surface of each of the protruding portions 32a and 32b. However, the method of forming the metal layers 70a and 70b is not limited thereto. By performing the step of forming the metal layers 70a and 70b, a fifth intermediate body 5M is obtained.

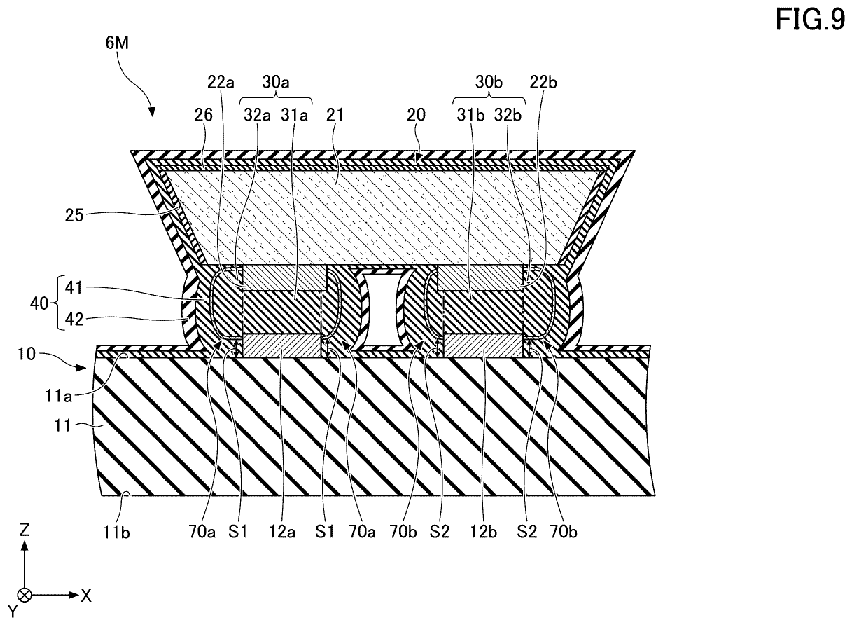

Subsequently, as illustrated in FIG. 9, the step of disposing the protective film 40 is performed. Specifically, the protective film 40 is formed by the atomic layer deposition method. First, the fifth intermediate body 5M is transferred into a chamber of a deposition apparatus for performing the atomic layer deposition method. Next, in the fifth intermediate body 5M, for example, two kinds of precursors are alternately supplied into a region around the electrically-conductive members 30a and 30b including the gaps S1 and S2. When the two kinds of precursors are alternately supplied, the electrically-conductive members 30a and 30b are heated to a temperature of 150° C. or more and 250° C. or less. As used herein, the phrase “heating the electrically-conductive members 30a and 30b to a temperature of 150° C. or more and 250° C. or less” is synonymous with setting a temperature in the chamber of the deposition apparatus to a temperature of 150° C. or more and 250° C. or less. The temperature in the chamber of the deposition apparatus can be measured by using a temperature sensor provided in the chamber, for example. Accordingly, the protective film 40 covering the gaps S1 and S2 can be formed.

The atomic layer deposition method is a film forming method capable of depositing atomic layers of the respective precursors one by one, and thus is suitable as a film forming method of covering the inside of narrow regions such as the gaps S1 and S2 with the protective film 40. Further, when the protective film 40 is formed by using the atomic layer deposition method, the gaps S1 and S2 can be widened according to the thermal expansion of the electrically-conductive members 30a and 30b by heating the electrically-conductive members 30a and 30b to a temperature of 150° C. or more and 250° C. or less. Accordingly, the protective film 40 can be brought into close contact with the upper surface 11a of the base 11, and can extend deeper into the gap S1 and into the gap S2. As a result, even when the electrically-conductive members 30a and 30b thermally expand after the protective film 40 is disposed, the protective film 40 and the base 11 are maintained to be in close contact with each other. That is, even when the electrically-conductive members 30a and 30b are exposed to a high-temperature environment, a gap is unlikely to be formed between the protective film 40 and the base 11. Accordingly, the possibility that the corrosive substance may enter the inside of the protective film 40 through a gap between the protective film 40 and the base 11 and corrode the electrically-conductive members 30a and 30b can be reduced. Accordingly, the light-emitting device 1 with high reliability can be obtained.

In the step of disposing the protective film 40, the protective film 40 is preferably disposed so as to cover the surfaces of the protruding portions 32a and 32b, the lateral surface covering layer 25, and the upper surface covering layer 26 in addition to the gaps S1 and S2. Accordingly, the possibility that the corrosive substance may enter the inside of the protective film 40 and corrode the electrically-conductive members 30a and 30b can be further reduced. Further, the protective film 40 is preferably disposed so as to integrally cover the lateral surface covering layer 25 and the upper surface covering layer 26. Accordingly, peeling of the lateral surface covering layer 25 and the upper surface covering layer 26 can be reduced. In addition, peeling of a boundary portion between the lateral surface covering layer 25 and the upper surface covering layer 26, which has relatively low adhesion to the semiconductor structure 21, can be reduced.

In the step of disposing the protective film 40, a first insulating film 41 and a second insulating film 42 having different linear expansion coefficients from each other are preferably sequentially disposed on the surface of each of the electrically-conductive members 30a and 30b. As an example, the first insulating film 41 is a film containing aluminum oxide, and the second insulating film 42 is a film containing silicon oxide. The first insulating film 41 and the second insulating film 42 may be disposed one by one. Alternatively, a plurality of first insulating films 41 and a plurality of second insulating films 42 may be disposed and may be alternately deposited. By disposing the protective film 40 including the first insulating film 41 and the second insulating film 42 having different linear expansion coefficients from each other, formation of a series of cracks penetrating through the protective film 40 can be reduced. As a result, the possibility that the corrosive substance may enter the inside of the protective film 40 and corrode the electrically-conductive members 30a and 30b can be reduced.

When the first insulating film 41 and the second insulating film 42 are disposed, the deposition apparatus alternately supplies two kinds of precursors for disposing the first insulating film 41 to the fifth intermediate body 5M inside the chamber, and then alternately supplies two other kinds of precursors for disposing the second insulating film 42 to the fifth intermediate body 5M inside the chamber. If a plurality of first insulating films 41 and a plurality of second insulating films 42 are disposed, the deposition apparatus repeats the above. By performing the step of disposing the protective film 40, a sixth intermediate body 6M is obtained.

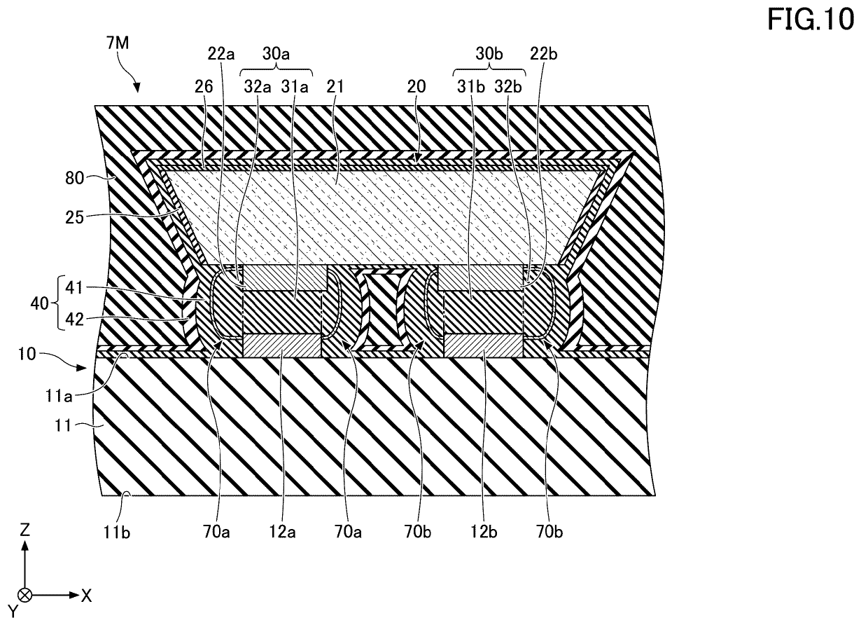

Subsequently, as illustrated in FIG. 10, the step of covering the upper surface and the lateral surfaces of the semiconductor structure 21 with the light-shielding member 80 is performed. Specifically, the lateral surfaces of the semiconductor structure 21 is covered by the light-shielding member 80 via the protective film 40 and the lateral surface covering layer 25. In addition, the upper surface of the semiconductor structure 21 is covered by the light-shielding member 80 via the protective film 40 and the upper surface covering layer 26. By performing the step of covering the upper surface and the lateral surfaces of the semiconductor structure 21 with the light-shielding member 80, a seventh intermediate body 7M is obtained.

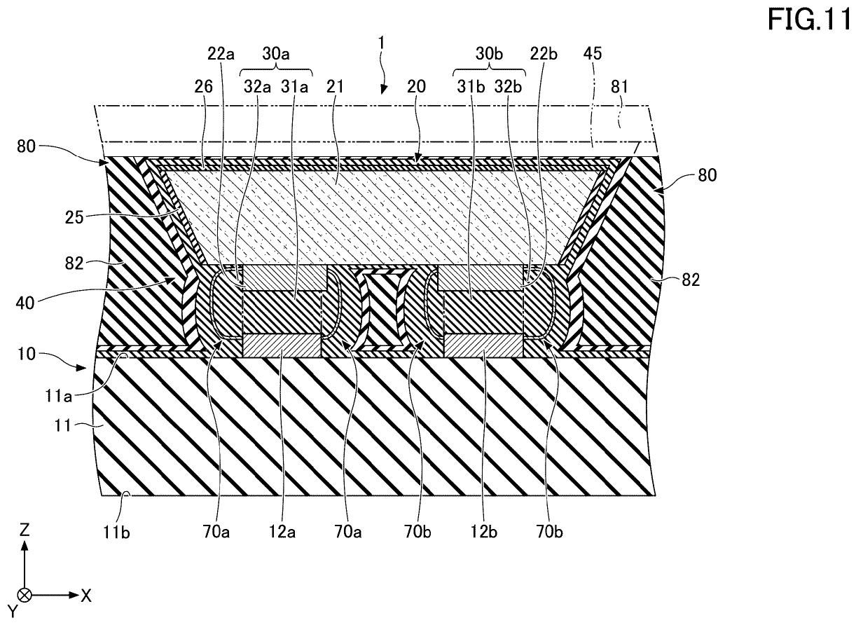

Subsequently, as illustrated in FIG. 11, the step of removing each of the region 81 of the light-shielding member 80 overlapping the upper surface covering layer 26 in a top view (hereinafter referred to as the “region 81 of the light-shielding member 80”) and the upper-side region 45 of the region of the protective film 40 overlapping the upper surface covering layer 26 in a top view (hereinafter referred to as the “upper-side region 45 of the protective film 40”) is performed.

Examples of a method of removing each of the region 81 of the light-shielding member 80 and the upper-side region 45 of the protective film 40 include a method of removing the region 81 of the light-shielding member 80 and the upper-side region 45 of the protective film 40 by spraying dry ice particles. Accordingly, a region 82 of the light-shielding member 80 covering the lateral surface covering layer 25 of the light-emitting element 20 remains. After the upper-side region 45 of the protective film 40 is removed, the thickness of a region covering the upper surface covering layer 26 becomes smaller than the thickness of a region covering the lateral surface covering layer 25. Accordingly, an influence of the protective film 40 on the light extraction efficiency of the semiconductor structure 21 can be reduced. However, the method of removing the region 81 of the light-shielding member 80 and the upper-side region 45 of the protective film 40 is not limited thereto.

Through the above steps, the light-emitting device 1 is obtained. However, the method of manufacturing the light-emitting device 1 may include other steps as appropriate. For example, the method of manufacturing the light-emitting device 1 may include a step of disposing a wavelength conversion member 90 above the light-emitting element 20 after the step of removing the region 81 of the light-shielding member 80 and the upper-side region 45 of the protective film 40 is performed. Further, in the method of manufacturing the light-emitting device 1, a step of disposing a wire 60 that electrically connects the substrate 10 and a package substrate 50 may be performed, and after the step of disposing the wire 60 is performed, a step of disposing a covering member 95 that covers the wire 60 may be performed.

According to one embodiment of the present disclosure, a method of manufacturing a light-emitting device with high reliability, and a light-emitting device can be provided.

Although embodiments have been described in detail above, the above-described embodiments are non-limiting examples, and various modifications and substitutions can be made to the above-described embodiments without departing from the scope of the claims.

1. A method of manufacturing a light-emitting device, the method comprising:
providing a substrate comprising a base, and a pair of wiring parts disposed on an upper surface side of the base;
providing a light-emitting element comprising a semiconductor structure, and a pair of electrodes disposed on a lower surface of the semiconductor structure;
disposing the light-emitting element above the substrate such that the pair of electrodes face the pair of wiring parts;
disposing an electrically-conductive member containing copper such that the electrically-conductive member electrically connects the pair of wiring parts to the pair of electrodes and comprises a body portion and a protruding portion, the body portion overlapping a corresponding wiring part of the pair of wiring parts in a top view, and the protruding portion protruding outward relative to the corresponding wiring part of the pair of wiring parts such that a gap is located between the protruding portion and the base; and
disposing a protective film at least in the gap by using an atomic layer deposition method in a state in which the gap is widened by heating the electrically-conductive member at a temperature of 150° C. or more and 250° C. or less.

2. The method of manufacturing the light-emitting device according to claim 1, wherein:
the disposing of the protective film comprises sequentially disposing a first insulating film and a second insulating film having different linear expansion coefficients from each other on a surface of the electrically-conductive member.

3. The method of manufacturing the light-emitting device according to claim 2, wherein:
the first insulating film contains aluminum oxide, and
the second insulating film contains silicon oxide.

4. The method of manufacturing the light-emitting device according to claim 1, further comprising:
disposing a lateral surface covering layer covering a lateral surface of the semiconductor structure, and disposing an upper surface covering layer covering an upper surface of the semiconductor structure, wherein:
in the disposing of the protective film, the protective film is disposed so as to integrally cover the lateral surface covering layer and the upper surface covering layer.

5. The method of manufacturing the light-emitting device according to claim 4, further comprising:
after the disposing of the protective film, covering the upper surface and the lateral surface of the semiconductor structure with a light-shielding member; and
removing each of a region of the light-shielding member overlapping the upper surface covering layer in the top view and an upper-side region of a region of the protective film overlapping the upper surface covering layer in the top view, wherein:
the upper surface of the semiconductor structure is a light extraction surface.

6. The method of manufacturing the light-emitting device according to claim 1, wherein:
the disposing of the electrically-conductive member comprises disposing a pair of electrically-conductive members comprising:
a first electrically-conductive member that electrically connects a first electrode of the pair of electrodes to a first wiring part of the pair of wiring parts, and
a second electrically-conductive member that electrically connects a second electrode of the pair of electrodes to a second wiring part of the pair of wiring parts, and
in a cross section passing through the semiconductor structure and the pair of electrodes, a center of the first electrically-conductive member of the pair of electrically-conductive members in a width direction is located outward relative to a center of the first electrode of the pair of electrodes in the width direction, and a center of the second electrically-conductive member of the pair of electrically-conductive members in the width direction is located outward relative to a center of the second electrode of the pair of electrodes in the width direction.

7. A light-emitting device comprising:
a substrate comprising a base, and a pair of wiring parts disposed on an upper surface side of the base;
a light-emitting element comprising a semiconductor structure, and a pair of electrodes disposed on a lower surface of the semiconductor structure;
an electrically-conductive member containing copper, electrically connecting the pair of wiring parts to the pair of electrodes, and comprising a body portion and a protruding portion, the body portion overlapping a corresponding wiring part of the pair of wiring parts in a top view, and the protruding portion protruding outward relative to the corresponding wiring part of the pair of wiring parts such that a gap is located between the protruding portion and the base;
a protective film covering at least the gap and comprising a first insulating film and a second insulating film having different linear expansion coefficients from each other.

8. The light-emitting device according to claim 7, wherein:
the first insulating film contains aluminum oxide, and
the second insulating film contains silicon oxide.

9. The light-emitting device according to claim 7, wherein:
the light-emitting element further comprises:
a lateral surface covering layer covering a lateral surface of the semiconductor structure, and
an upper surface covering layer covering an upper surface of the semiconductor structure, and
the protective film further integrally covers the lateral surface covering layer and the upper surface covering layer.

10. The light-emitting device according to claim 9, wherein:
the upper surface of the semiconductor structure is a light extraction surface from which light emitted from the semiconductor structure is extracted, and
a thickness of a region of the protective film covering the upper surface covering layer is less than a thickness of a region of the protective film covering the lateral surface covering layer.

11. The light-emitting device according to claim 7, wherein
the electrically-conductive member comprises a pair of electrically-conductive members comprising:
a first electrically-conductive member that electrically connects a first electrode of the pair of electrodes to a first wiring part of the pair of wiring parts, and
a second electrically-conductive member that electrically connects a second electrode of the pair of electrodes to a second wiring part of the pair of wiring parts, and
in a cross section passing through the semiconductor structure and the pair of electrodes, a center of the first electrically-conductive member of the pair of electrically-conductive members in a width direction is located outward relative to a center of the first electrode of the pair of electrodes in the width direction, and a center of the second electrically-conductive member of the pair of electrically-conductive members in the width direction is located outward relative to a center of the second electrode of the pair of electrodes in the width direction.
